(19) United States
(12) Patent Application Publication
(10) Pub. No.: US 2015/0255200 A1
(43) Pub. Date: Sep. 10, 2015

(54) Fast Superconducting Switch for Superconducting Power Devices

(71) Applicant: BROOKHAVEN SCIENCE ASSOCIATES/BROOKHAVEN NATIONAL LABORATORY, Upton, NY (US)

(72) Inventors: Vyacheslav Solovyov, Rocky Point, NY (US); Qiang Li, Setauket, NY (US)

(21) Appl. No.: 14/432,787

(22) PCT Filed: Oct. 8, 2013
(86) PCT No.: PCT/US2013/063869

§ 371 Date: Apr. 1, 2015

Related U.S. Application Data
(60) Provisional application No. 61/713,127, filed on Oct. 12, 2012.

(51) Int. Cl. H01F 6/00; H01L 39/22

(52) U.S. Cl. CPC H01F 6/003; H01L 39/228

(57) ABSTRACT

A superconducting magnetic energy storage device that can maintain a large ratio of the stored energy to the static energy loss, and has the ability to by-pass the current through a fast, high-voltage superconducting switch. More particularly, this invention relates to the design and application of novel high-voltage superconducting switch provided with a direct heating of the active superconducting layer through a metal substrate either by transport or by inductive current, and the protection of the superconducting layer by cryogenically-cooled metal-oxide-semiconductor field-effect transistors.

### CROSS-REFERENCE TO RELATED APPLICATIONS

This application claims the benefit of U.S. Provisional Application Ser. No. 61/713,127, filed on Oct. 12, 2012, the specification of which is incorporated by reference herein in its entirety for all purposes.

### STATEMENT OF GOVERNMENT LICENSE RIGHTS

The present invention was made was made with Government support under contract number DE-ACO2-98CH10886 awarded by the U.S. Department of Energy. The Government has certain rights in the invention.

### FIELD OF THE INVENTION

The present invention relates to superconducting magnetic energy storage devices that can maintain a large ratio of the stored energy to the static energy loss, and have the ability to by-pass the current through a fast, high-voltage superconducting switch. More particularly, this invention relates to the design and application of a novel high-voltage superconducting switch provided with a direct heating of the active superconducting layer through a metal substrate either by transport or by inductive current, where the superconducting layer is not stabilized with normal metal and is kept protected during the transition from normal to superconducting state and back by cryogenically-cooled metal-oxide-semiconductor field-effect transistors.

### BACKGROUND

Superconducting magnetic energy storage (SMES) is attracting attention as an alternative to chemical and electromechanical energy storage. SMES is a grid-enabling device that stores and discharges large quantities of power almost instantaneously. The system is capable of releasing high levels of power within a fraction of a cycle to replace a sudden loss or dip in line power. Strategic injection of brief bursts of power can play a crucial role in maintaining grid reliability especially with today's increasingly congested power lines and the high penetration of renewable energy sources, such as wind and solar.

A typical SMES consists of two parts: a cryogenically cooled superconducting coil and a power conditioning system as shown in FIG. 1. Ideally, once the superconducting coil is charged, the current will not decay and the magnetic energy can be stored indefinitely. This is typically called a “persistent mode.” In the persistent mode, once the magnet has been energized, the windings are short-circuited with a persistent switch to create a closed superconducting loop. The power supply can be turned off and persistent currents may theoretically flow for months, preserving the magnetic field. The advantage of this persistent mode is that no energy is needed to power the windings. The current circulating through the superconducting coil may be on the order of 1 kA. At such time as utility-fed power to power conditioning system is lost, the switch can be opened and the energy stored in the magnetic field of the magnet can be automatically applied to the power conditioning system in the form of electrical current, since the switch is no longer shunting current from power conditioning system.

FIG. 1 is a schematic representation of a conventional SMES system 30 for providing backup power to system load 20, by way of power conditioning system 10. System load 20 is not particularly limited and can include any type of devices for residential, commercial and industrial purposes such as electronics, appliances, electrical equipment, or any electrical motor driven equipment. Power conditioning system 10 includes conventional circuitry, such as inverters and transformers, for receiving power from the utility and from SMES system 30, and for distributing, regulating, and applying the received power to system load 20 in the conventional fashion. In persistent mode operation, system load 20 receives its power from the utility via the power conditioning system 20. However, as shown in FIG. 1, upon loss of power from the utility, system load 20 can switch and receive temporary backup power from SMES system 30.

Conventional SMES system 30 in FIG. 1 includes a superconducting magnet 33, which can be constructed in the conventional manner as a coil of superconducting wire maintained at superconducting temperatures by cryostat 32. Cryostat 32 is cooled by a refrigeration system 31. The superconducting magnet 33 is part of an electrical circuit that includes a superconducting switch 35, which is located inside of cryostat 32, although previous designs of SMES system 30 also had the switch 35 located outside of the cryostat 32. Typically, the persistent switch 35 is made from a piece of superconductor connected across the winding ends of the magnet 33 that can be selectively operated in the superconducting and resistive regions. A converter 36 is also typically provided to convert DC voltage/current coming from the SMES system to AC 60 Hz voltage of the power utility system 10.

A superconducting material of the switch 35 is in a superconducting state when operated within a window of permissible ranges of temperature, external magnetic field, and current. Thus, the persistent switch 35 can operate by changing either the temperature, current, or magnetic field of the superconducting material from within the superconductivity window to an operating point outside of the superconducting range, thus normalizing the material (i.e., switching its operation from superconducting to a resistive state).

As illustrated in FIGS. 2A and 2B, a conventional persistent switch 35 of the thermal type operates by heating the superconducting material 37 to a temperature above its superconducting critical temperature. One known thermal persistent switch includes a resistive wire wound about the superconducting wire. Normalization of the superconducting material is effected by applying a DC current to the resistive wire, heating the superconducting material to above its critical temperature. In this conventional persistent switch, the resistive wire must be electrically insulated from the superconducting wire. However, because electrical insulating materials are also generally thermally insulating, the efficiency and speed with which the superconducting wire can be heated in these switches is damped by the electrical insulator. As such, conventional thermally-switched persistent switches do not have sufficiently rapid switching times for many applications, such as SMES systems. For example, niobium-tin (Nb₃Sn) persistent switch developed for the Japanese Maglev train weighs 46 kg and has an average switching time of 2 minutes (Tomita, M., et al. “Switching reaction of Nb3Sn persistent current switch with a high current capacity.” Physica C: Superconductivity, 2001. 357-360 (Part 2): p. 1336-1341; incorporated herein by reference in its entirety). Slow transition between storage and drive modes negates the main advantage of SMES, which is the capability of delivering a large amount of power almost instantly. Therefore, there is still a continuing need to develop new fast superconducting switches for SMES devices that would allow for a rapid response time, and yet it would have a low-weight and remain stable.

### SUMMARY

In view of the above-described problems, needs, and goals, a new ultra-low resistance, fast, and light-weight persistent switch is provided that has a low thermal mass and fast response time. It is contemplated that such persistent switch can be employed in a conventional SMES system for storage of electricity.

Generally, the persistent switch is driven to the normal state by heating a metal substrate of the switch either directly or inductively. This is respectively achieved by passing alternating current (AC) directly through the metal substrate or through an inductive heater located in close proximity to the substrate.

In a preferred embodiment, the persistent switch also employs a by-pass module to protect the switch during the transition from the normal state to superconducting. The by-pass module preferably includes one or more low-resistance metal oxide semiconductor field-effect transistors (MOSFETs) mounted directly on the superconducting leads, which allows forgoing passive protection in form of metal coating of the superconducting wire. By using superconducting wire without stabilizer, the switch resistance can be substantially increased while keeping the thermal mass low. Specifically, the by-pass module can be opened during the transition period preventing the voltage rise that can damage the switch.

In one embodiment, an energy storage system has a cryostat, a superconducting electromagnet and a persistent switch short circuited in a loop and disposed within the cryostat. The ultra-low resistance, fast, and light-weight persistent switch is coupled to the first and second leads of the superconducting electromagnet. Generally, the present superconducting energy storage system is operated by conducting current through the superconducting electromagnet and the persistent switch.

The persistent switch has two main components. First, the persistent switch has a heating element, which can be the metal substrate of the superconducting wire. Second, the persistent switch has a switch wire, which is a length of wire having at least one strand of superconducting material in thermal contact with the metal substrate, which is the heating element. The switch wire is made from a superconducting material that has a critical temperature between 60 K and 120 K. When in its superconducting state, the persistent switch shunts the current conducted by magnet, preventing the current from exiting the cryostat and being drawn by power conditioning system. In contrast, at a desired time, the heating element can be engaged by passing an alternating current directly through the heating element, or by passing alternating current through an inductive heater disposed in close proximity to the heating element. In either case, the temperature of the heating element is raised, thereby raising the temperature of the superconducting switch wire in thermal contact with the heating element above its critical temperature. At such temperature, the switch wire becomes resistive. When resistive, the persistent switch presents a greater impedance to the magnet than the power conditioning system, in which case the current conducted by magnet is applied to power conditioning system.

The persistent switch further preferably has a third component in the form of a by-pass module coupled to the first and second leads of the magnet to protect the switch during the transition from the resistive state back into the superconducting state. To reenergize or recharge the magnet, a DC power source, either independent or as part of the power conditioning system drives the current through the magnet until the persistent switch transitions from the resistive (normal) state into the superconducting state, in which case the current conducted by the magnet will be short-circuited with the persistent switch to create a closed superconducting loop. To protect the persistent switch during the transition from the resistive state into superconducting state, the by-pass module is opened up to prevent voltage rise to damaging levels.

Energy storage applications require frequent transitions of the magnet from storage to discharge mode. Every transition has the energy penalty due to heating and cooling of the switch. By implementing the active protection in the form of the by-pass module, the metal stabilizing layer, which would typically be provided to protect the switch from damaging voltage rise, is eliminated, which reduces the thermal mass of the switch by a factor of 3 and increases the “off” resistance by a factor of 1000.

The switch may also be implemented into a backup power system of the SMES (Superconducting Magnetic Energy Storage) type, in which the persistent switch is included within the same cryostat as the magnet itself, and connected in parallel with the magnet. Normalization of the persistent switch, by applying an AC current to the switch, directs current from out of the magnet into the power conditioning system as backup power. The switching time of the persistent switch is sufficiently fast to maintain the power levels in the system load for sufficient time to permit backup generators or other long-term backup systems to begin operation.

These and other characteristics of the persistent switch and SMES systems that employ such a switch will become more apparent from the following description and illustrative embodiments, which are described in detail with reference to the accompanying drawings. Similar elements in each figure are designated by like reference numbers and, hence, subsequent detailed descriptions of such elements have been omitted for brevity.

### BRIEF DESCRIPTION OF THE DRAWINGS

FIG. 1 is a schematic diagram showing a conventional SMES setup.

FIGS. 2A-2B are two schematic diagram of the conventional SMES setup with a thermal persistent in “OFF” (FIG. 2A) and “ON” (FIG. 2B) modes.

FIG. 3A is an electrical diagram of a persistent switch according to one embodiment of the present disclosure.

FIG. 3B is an electrical diagram of a persistent switch according to an alternative embodiment of the present disclosure.

FIG. 4 is a cross-sectional rendering of a superconducting switch wire.

FIG. 5 is a rendering of a persistent switch having multiple superconducting switch wires.

FIG. 6 is an electrical diagram of the persistent switch shown in FIG. 5.

FIG. 7A is a photograph of a partially assembled switch. By-pass MOSFETS are on top.

FIG. 7B is a photograph of the fully assembled switch with a 6″ 2 G wire coil.

FIG. 8A is a plot of the channel resistance (mΩ) of 400 A MOSFET in 300 to 10 K temperature range as a function of temperature.

FIG. 8B is a plot comparing time decay of magnetic field inside a superconducting coil in the MOSFET by-pass mode (only MOSFET bypass is on) and superconducting bypass mode (the superconducting bypass is on.

FIG. 9 is a plot showing time profiles of the switch quench.

FIG. 10 is a circuit diagram of a circuit for delivering opposite current through the switch during a re-closure phase.

FIG. 11A is a plot showing a time profile of the switch recovery.

FIG. 11B is a plot showing the continuous operation of the switch.

FIG. 12 is a plot that illustrates the operation of the superconducting switch in the long-term storage mode.

FIG. 13 is a plot showing the expanded profile of the partial discharge of the coil at 75 A current.

FIG. 14 is a plot showing a long term relaxation of the axial field component at 10 A and 70 A coil current.

### DETAILED DESCRIPTION

A superconducting persistent switch having a light-weight configuration with low thermal mass and fast response time is disclosed. The persistent switch can be employed in a conventional SMES system for storage of electricity. Generally, the persistent switch is driven to the normal state by heating a metal substrate of a superconducting switch wire by passing alternating current (AC) directly through the metal substrate or by inductively heating the metal substrate. To protect the switch during the transition from the normal state to superconducting, the switch can employ a by-pass module, preferably made from one or more low-resistance metal oxide semiconductor field-effect transistors (MOSFETs) mounted directly on the superconducting leads, which allows minimization of the overall circuit resistance. Specifically, the by-pass module can be opened during the transition period preventing the voltage rise to damaging levels. This allows elimination of the passive metal protection layer of the superconducting wire.

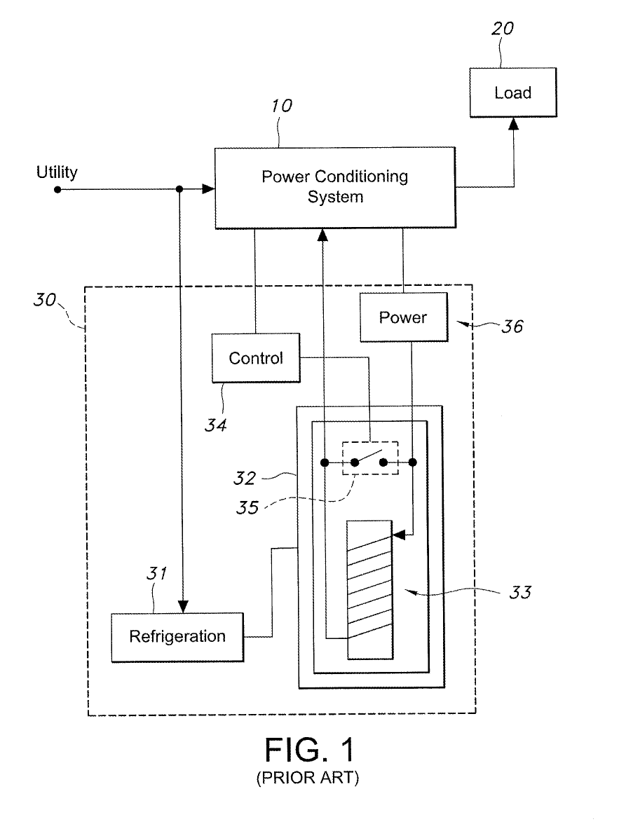

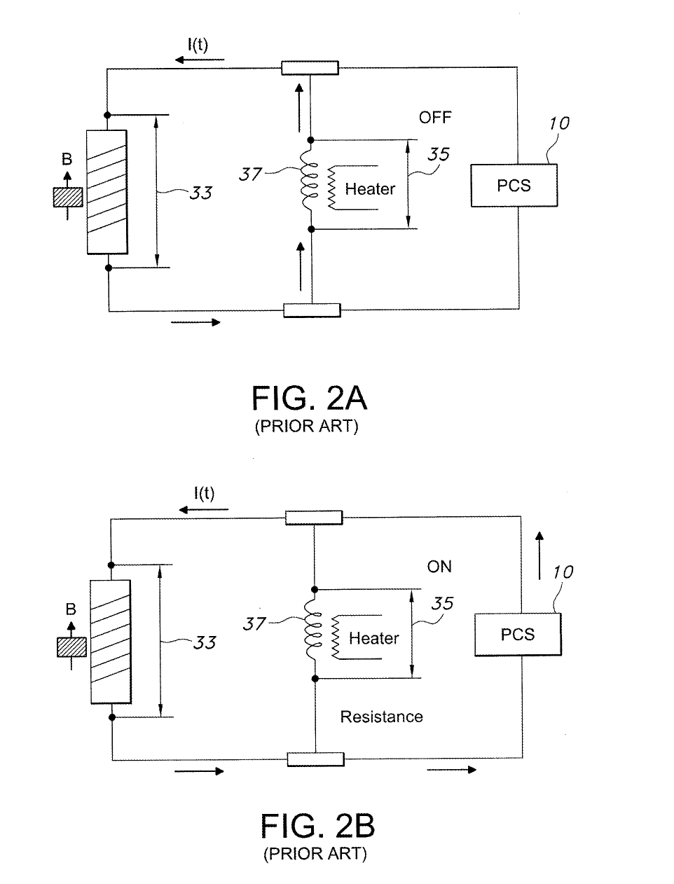

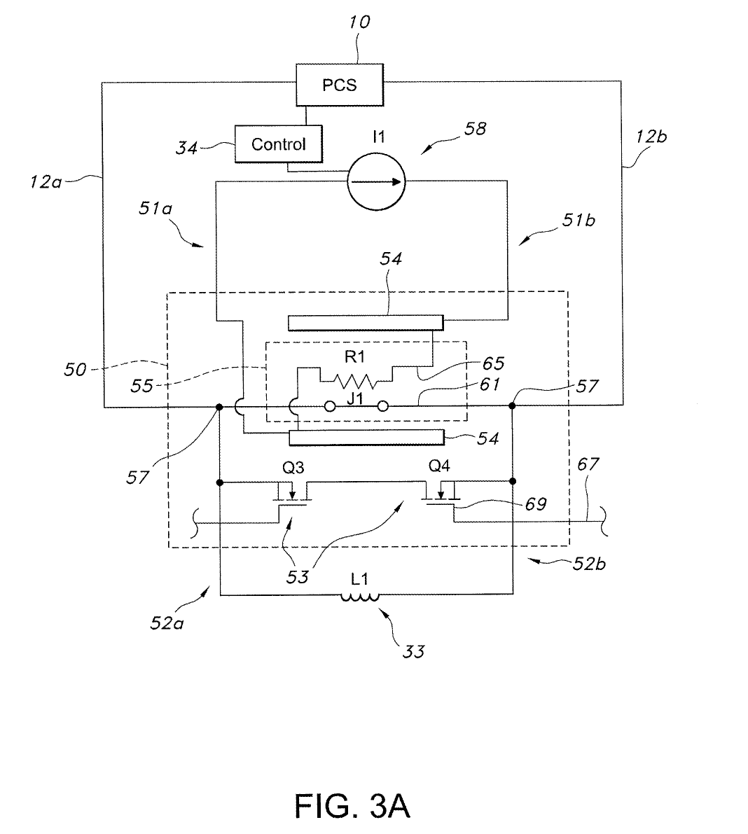

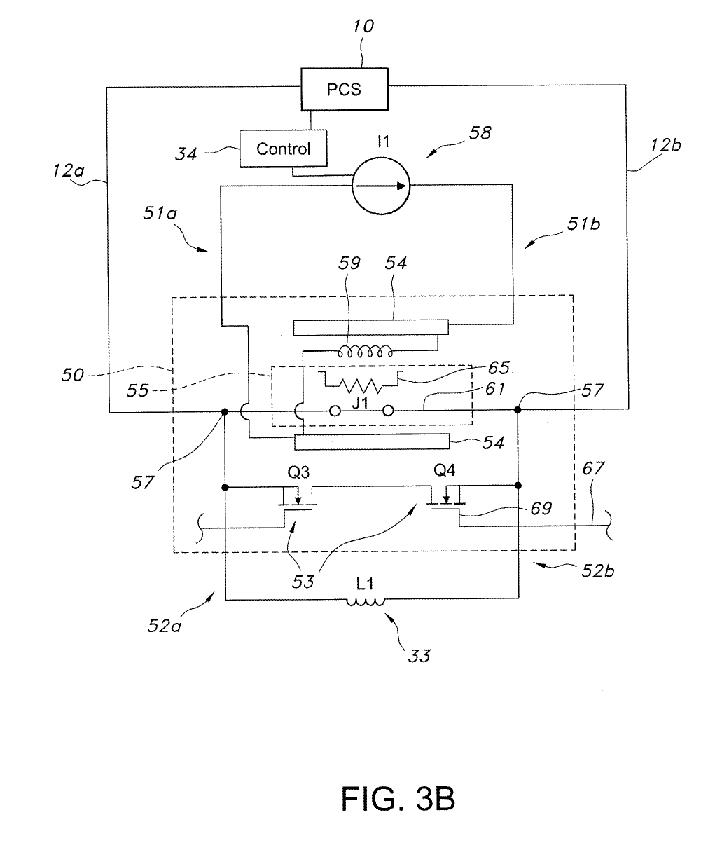

As illustrated in FIG. 3A, an energy storage system includes a cryostat (not shown in FIG. 3A or FIG. 3B), such as the cryostat 32 illustrated in FIG. 1 and FIG. 2 described above, which is a conventional insulated container for maintaining very low temperatures, such as 4.2 K or lower, as necessary to maintain superconducting materials in their superconducting state. Superconducting magnet 33 is located within the cryostat, and is constructed in the conventional manner for SMES systems as a coil of superconducting wire surrounding an iron or non-ferromagnetic bore, as desired. The superconducting wire in magnet 33 (also identified as L1) can be made from any superconducting material such as yttrium-barium copper oxide (YBCO), bismuth strontium copper calcium oxide (BiSCCO) niobium-tin (Nb₃Sn), niobium-titanium (NbTi) alloy, or vanadium-gallium (V₃Ga). The size of the magnet 33 is preferably sufficient to carry at least 100 Ampere (A) or more current, and has sufficient turns so as to store the desired amount of energy for use as backup power. For example, energy equivalent to 10 kW of power for 200 seconds of carry-through to power conditioning system may be stored by magnet 33.

Persistent switch 50 is connected in parallel with magnet 33 by two superconducting leads 52a and 52b, that are preferably made from the same superconducting material as the magnet 33 itself. Persistent switch 50 is also located within cryostat (not shown) and is constructed of a superconducting material in such a manner as to be selectively normalized by the application of an alternating current to leads 51a and 51b that either heats the persistent switch directly or by inductance of an eddy current within the switch 50, as will be discussed in further detail below. When in its superconducting state, the persistent switch 50 shunts the current conducted by magnet 33, preventing the current from exiting cryostat. In contrast, when resistive, persistent switch 50 presents a greater impedance to magnet 33 than power conditioning system 10, in which case the current conducted by magnet 33 will be applied via leads 12a and 12b to power conditioning system 10.

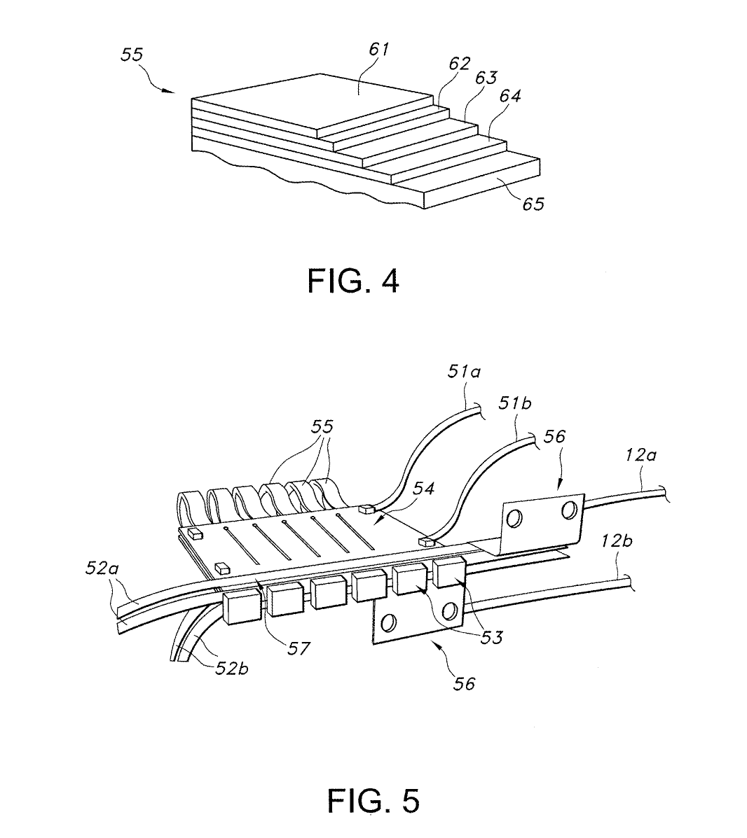

As further illustrated in FIG. 4 and FIG. 5, the persistent switch 50 according to one embodiment is constructed from stabilized superconducting switch wire 55 sandwiched between two metal terminal plates 54. The superconducting switch wire 55 having the desired cross-sectional shape and size is preferably superconductive at temperatures above 60 K, more preferably at temperatures between 60 and 110 K. For example, the superconducting switch wire 55 can be fabricated from yttrium barium copper oxide (YBCO; =93 K) or bismuth strontium calcium copper oxide (BiSCCO; Bi-2212 has T_{c}≈95 K, Bi-2223 has T_{c}≈108 K, and Bi-2234 has T_{c}≈104K) to form a superconducting layer 61 between 0.5 and 10 μm in thickness (see FIG. 4), preferably about 1 μm YBCO layer. Once, the superconducting wire reaches a critical temperature of the underlying superconducting material, it becomes resistive.

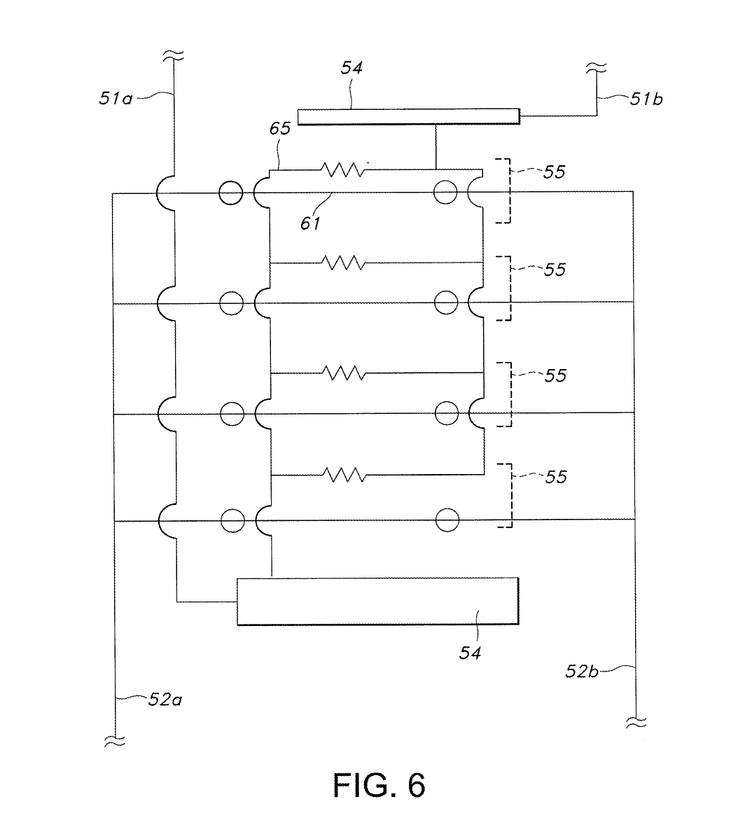

As illustrated in FIG. 5 and FIG. 6, a plurality of switch wires 55 may be connected in parallel between the terminal plates 54, to add more current depending on the amount of current to be delivered by the system. The number of switch wires 55 sandwiched between the terminal plates 54 is not particularly limited and can be as low as one and as high as 10. In one embodiment, the number of switch wires 55 is 6 such that the overall dimension of the switch wires 55 is about 10 mm by 20 cm. While the switch wires 55 are shown to make one smooth turn (one undulation) between the terminal plates 54, thereby having leads 52a and 52b positioned near each other in order to afford a direct placement of the by-pass module 53 between leads 52a and 52b, in another embodiment the tapes can also easily make multiple undulations. In such embodiment, the switch wire 55 can make multiple undulations between the terminal plates to meet the leads 52a and 52b in a similar fashion as shown in FIG. 5. The terminal plates 54 provide mechanical support for the switch wires 55 and also provide a means for electrical connection between the heating element 65 of each switch wire and an AC power source 58, as will be described in further detail below.

The switch wire 55 can be constructed by conventional techniques, such as winding the tape on a round mandrel. Alternatively, a commercially available example of a superconducting wire suitable for use as the switch wire 55 is 10 mm wide wire available from SuperPower Corp. (Schenectady, N.Y.).

Referring to FIG. 4, in addition to a superconducting layer 61, the switch wire 55 has a heating element 65 fabricated to be layered in close proximity to the superconducting layer 61. As shown in FIG. 3A and FIG. 6, the superconducting layer 61 of each switch wire is electrically connected in parallel between leads 52a and 52b of the magnet 33, as well as between leads 12a and 12b of the power conditioning system 10. The heating element 65, on the other hand, is not electrically connected to the magnet/power conditioning circuit, but instead is disposed in thermal contact with the superconducting layer 61 so as to efficiently heat the superconducting layer.

The heating element 65 of the switch can be fabricated from nickel, nickel-tungsten alloy, stainless steel, or superalloy (e.g., hastelloy). In one embodiment, the heating element 65 is between 20 and 100 μm thick, although preferably about 50 μm. The heating element 65 is in close thermal contact with the superconducting layer 61, but is electrically isolated from the superconducting layer by the provision of additional electrically insulating protective layers disposed between the heating element and the superconducting layer. In particular, the switch wire 55 includes an oxide buffer layer 62 made, for example, of zirconium oxide and aluminum oxide, to prevent electrical contact between the superconductor and the heating element 65. In addition to the oxide buffer layer 62, the switch wire 55 can also have oxide layers 63 and 64, made from a material, such as lanthanum manganese oxide, designed to improve structural compatibility of the YBCO layer 61 and the heating element 65.

In one embodiment, as shown in FIG. 3A and FIG. 6, the heating element 65 is heated directly by passing an alternating current through the heating element. In this case, each heating element 65 is electrically connected to a power source 58 that can generate an alternating current (AC) at frequencies of 100 to 400 kHz. As mentioned above, the switch wires 55 are structurally supported by the terminal plates 54 and, in this embodiment, each heating element 65 of each switch is electrically connected in parallel between the opposite terminal plates 54. The terminal plates 54 are, in turn, electrically connected to the AC power source via copper leads 51a and 51b. Thus, each switch wire 55 is electrically connected to two separate electrical circuits. The first circuit is the primary SMES system circuit, while the second circuit is a secondary heating circuit.

In an alternative embodiment, as shown in FIG. 3B, the switch wire 55 can transition into its resistive state by inductive heating of the heating element 65. In this embodiment, a power source 58 sends an AC current through an inductive heater 59 disposed in close proximity to each heating element 65. The inductive heater 59 can be mechanically supported by and electrically connected to the terminal plates 54, which, in turn are electrically connected to the AC power source 58 via leads 51a and 51b. In this case, the heating element 65 of the switch wire 55 is not electrically connected to the AC power source 58, but is heated inductively by the AC power source delivering current to the inductive heater 59. Thus, the heating circuit in this embodiment induces circulating eddy currents within the heating element 65 sandwiched between the two terminal plates 54. These eddy currents flow against the electrical resistivity of the metal, generating precise and localized heat without any direct contact between the switch wire 55 and the terminal plates 54. Since about 85% of the heating effect occurs on the surface or “skin” of the switch wire 55, thin tape-shaped strands of the switch wire 55 are most preferable.

To reenergize or recharge the magnet 33, a DC power source either independent or as part of the power conditioning system 10 drives the current through magnet 33 until persistent switch 50 transitions from the resistive (normal) state back into the superconducting state. This causes a drop of the voltage across the switch, which allows the switch to cool down and become superconductive again. With the persistent switch 50 back in the superconducting state, the current conducted by magnet 33 will again be short-circuited by the persistent switch 50 to create a closed superconducting loop.

To protect the persistent switch 50 during the transition from the resistive state back into the superconducting state, the switch 50 is preferably provided with a by-pass module 53 connected in parallel with the superconducting layer 61 between the leads 52a and 52b of the magnet. The role of the by-pass module 53 is to prevent sudden voltage rise to damaging levels during the transition of the superconducting layer 61 of the switch wire 55 from its resistive state to its superconductive state. In particular, once the superconducting layer 61 of the switch wire 55 is in the normal resistive state, the by-pass module 53 can be opened. This can be done by activating an external drive circuit 67 electrically connected to the by-pass gate module 53 to actively open and close the by-pass module allowing current to pass through the by-pass module, and the voltage can rise to the operating level, corresponding to the “off” state. In the recovery phase, the switch wire 55 transitions from normal resistive “off” state to superconducting “on” state and the by-pass module 53 is turned on or opened by supplying high voltage to the external drive circuit 67 to allow the switch wire 55 to cool down. In a preferred embodiment, the external drive circuit 67 is connected to and controlled by the same controller 34 used to activate the power source 58 used for heating the heating element.

The by-pass module 53 preferably includes one or more low-resistance metal oxide semiconductor field-effect transistors (typically referred to as power MOSFETs) operable between 60 and 77 K. As illustrated in FIG. 3A and FIG. 3B, the by-pass module 53 can have 2 power MOSFETS (marked as Q3 and Q4), whose respective gates 69 are electrically connected to and controlled by the external drive circuit 67. These bypass MOSFETS are opened up by the external gate drive circuit 67 to prevent voltage rise to damaging levels during the transition phase. Once the switch 50 has returned to the superconducting state, the bypass MOSFETS are closed (high-imedence state), thereby preventing current from passing through the by-pass module. Preferably, the external gate drive circuit 67 opens and closes the MOSFETs with a predefined timing sequence.

The number of power MOSFETS is not particularly limited and can range between 1 and 10 depending on the configuration of the overall system. For example, in the persistent switch 50 illustrated in FIG. 5, the by-pass module 53 has 6 power MOSFETS, each positioned across from each strand 61 of the switch wire 55 and directly connected to the leads 52a and 52b. Direct mounting of MOSFETs allows minimization of the overall circuit resistance.

The power MOSFETs preferably have channel resistance minimum near 60 to 80 K for optimal protection and improved performance. An example of the commercially available power MOSFET that can be used in the persistent switch 50 is a 400 A IRFS3004-7PPBF, N-channel silicon based power MOSFET manufactured by International Rectifier Inc. (El Segundo, Calif.). The device features ultra-low resistance of the channel, below 900μΩ at room temperature, which falls by a factor of 3 when the device is cooled down to 77 K. This property of the device enables development of an active (i.e., it does not add up to the off-resistance), ultra-low resistance shunt that protects the superconducting switch during the transitions.

Referring back to FIG. 5, the persistent switch 50 further has a plurality of low-resistance joints 57 and two bus bars 56. The low-resistance joints 57 are used to connect leads 52a and 52b with the superconducting layer 61 of the switch wire 55. Since the primary source of the loss during the transition is dissipation in the joints 57, it is preferred that the joints 57 are made from a low resistance material such as indium-silver alloy.

In contrast, the bus bars 56 link leads 52a and 52b with leads 12a and 12b of the power conditioning system 10. The size of the bus bar determines the maximum amount of current that can be safely carried. Bus bars can have a cross-sectional area of as little as 10 mm², although, for the SMES system the bus bar 56 is a preferably flat strip of copper having a cross-section area of 100 microns. While it is preferred that bus bar provided for the persistent switch 50 is flat strip, a hollow tubes can also be used as long as it allows heat to dissipate more efficiently due to its high surface area to cross-sectional area ratio.

The operation of the disclosed persistent switch 50 in the context of a conventional superconducting energy storage system 30, as illustrated in FIG. 1, will now be described. It is to be understood, however, that those skilled in the art may develop other structural and functional modifications without significantly departing from the scope of the disclosed invention. In the initial stage of system operation, the superconducting electromagnet 33 is energized. The refrigeration system 31 has cooled cryostat 32 to superconducting temperatures, such as 60 K or lower, and magnet 33 is conducting current, such as on the order of 1-5 kA, at a magnetic field suitable to maintain its superconducting state. The AC power source 58 is off at this point, and as such only the DC current through magnet 33 is applied to switch 50. Switch 50 is in a superconducting state at this point and thus provides virtually no resistance across leads 52a, 52b. The superconducting state of switch 50 permits it to conduct the entirety of the current conducted by magnet 33, and as such energy storage system is in its persistent state.

In the event that power conditioning system 10 undergoes a power loss from the utility, a controller 34 will issue a signal to the AC power source 58 to generate high frequency AC current across leads 51a and 51b in order to either pass current through the heating element 65 directly, as shown in FIG. 3A, or to pass current through the inductive heating element 59 to heat the heating element indirectly, as shown in FIG. 3B. In either case, heating of the heating element 65 will initiate the shunting of the switch 50 into its resistive mode. As described above, in a preferred embodiment, the high frequency AC current first passes through the plates 54 that surround (“sandwich”) the switch wire 55 of the persistent switch 50, thereby generating a rapid heating of the heating element 65. It is contemplated that the time required for the switch wire 55 to normalize (i.e., become resistive) is on the order of milliseconds, for example 1 to 100 ms. The resistance of switch 50 then becomes substantial at this point in the operation, for example on the order of 10-100Ω, which is larger than the impedance for passing the current across leads 12a and 12b. The current conducted by magnet 33 is then substantially dissipates from the superconducting magnet system towards the power conditioning system 10, which in turn applies backup power to system load 20 for a desired duration that can range anywhere from 1 to 10 seconds.

Depending on the necessity of the power conditioning system 10, the magnet 33 will not necessarily discharge its full capacity before the backup power needs are satisfied. At this point, the controller 34 will issue a signal to the AC power source 58 to stop generating high frequency AC current across leads 51a and 51b in order to initiate cooling of the switch 50 into its superconducting state. However, as mentioned above, during the transition period, the voltage can rise to levels that can typically damage the switch 50 and make it unusable for continuous operation. To avoid such damage, the switch 50 employs the by-pass module 53, as discussed above. Specifically, once the switch wire 55 is in the normal resistive state, the by-pass module 53 can be opened and the voltage can rise to the operating level, corresponding to the “off” state. In the recovery phase the switch wire 55 transitions from normal resistive “off” state to superconducting “on” state and the by-pass module 53 is turned on to allow the switch wire 55 to cool down.

To speed up the recovery process, a circuit 70 which delivers an opposite current through the switch wire 55 during re-closure phase can be implemented, as shown in FIG. 10. The circuit 70 is the same as that shown in FIGS. 3A and 3B, in that it includes the super-conducting magnet coil 33, the switch 55 and the by-pass module 53 connected in parallel (the power conditioning system not being shown in FIG. 10). However, in this embodiment a capacitor 72 (C1) connected in series with an additional MOSFET 74 (M1) are together connected in parallel with the super-conducting magnet coil 33, the switch 55 and the by-pass module 53.

The capacitor 72 (C1 in FIG. 10) is charged to an opposite voltage with respect to the voltage present on the coil 33 by an external power source or by the coil itself. During the recovery, the MOSFET 74 (M1) modulates voltage on the switch 55 (S1) so that the current through the switch 55 (S1) reverses direction for a short period of time, typically 1-3 ms. The MOSFET 74 is actively driven by an external circuit when fast switch recovery may be required. This is sufficient for the switch recovery. It is contemplated that the time required for switch wire 55 to become superconducting again is on the order of a milliseconds, for example 1 to 20 ms.

Based on FEM analysis, the switch closing time is predicted to recover and close within 10 ms. However, the observed experimental recovery time can exceed several seconds, especially for large current, because cooling of the superconductor does not occur uniformly. Usually a “hot spot,” which is an area with high temperature, develops in the tape bulk. The “hot spot” takes a long time to cool down. In a preferred embodiment, to speed up the recovery process, a circuit which delivers an opposite current through the switch wire 55 during re-closure phase can be implemented (see FIG. 10). This configuration allows for a fast, less than 3 ms switch closure.

While the persistent switch, the energy storage system incorporating such persistent switch and SMES based on such energy storage system have been described in connection with what is presently considered to be the most practical and preferred embodiment, it is to be understood that the invention is not to be limited to the disclosed embodiments, but on the contrary, is intended to cover various modifications and equivalent arrangements included within the spirit and scope of the appended claims.

### EXAMPLES

### Example 1

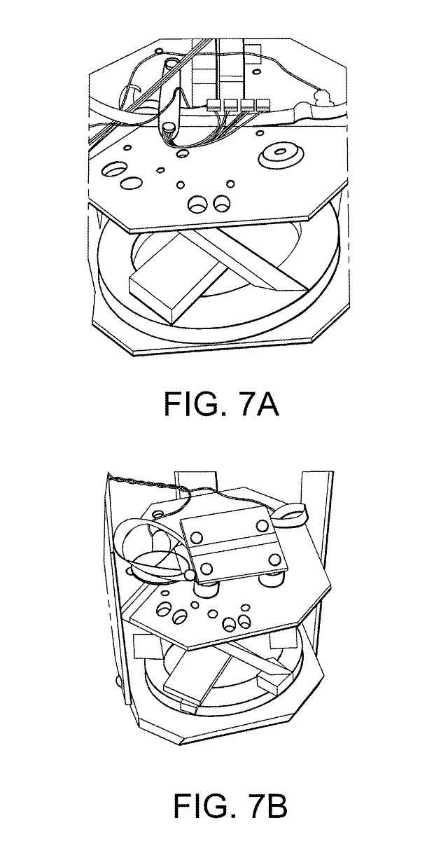

FIGS. 7A and 7B illustrate the assembled persistent switch. The switch frame was manufactured from 5×15 cm, 0.125″ thick G10 fiberglass. A middle 20 cm part of 30 cm long coupon of 12 mm wire YBCO tape was stripped of copper stabilizer. The YBCO layer was etched to form 10 mm wire strip. The heater wires were soldered directly to the substrate. The N-channel silicon based power MOSFET (400 A IRFS3004-7PPBF; International Rectifier Inc. El Segundo, Calif.) bypass was mounted directly on the copper-coated leads of the wire coupon. The whole assembly was clamped with ¼″ G10 fiberglass.

### Example 2

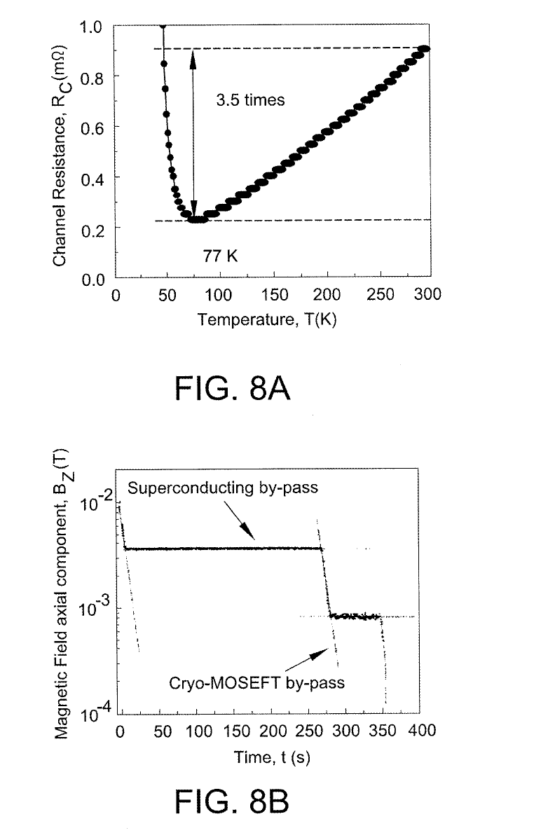

FIG. 8A shows the open channel resistance of a 400 A International Rectifier power MOSFET employed in the persistent switch of Example 1 between 10 K and 300 K. The channel resistance reaches a minimum at 77 K which makes this type of device an optimal choice for the active protection. The achieved channel resistance reduction is by about 3.5×.

FIG. 8B illustrates operation of the switch in cryo-MOSFET by-pass and superconducting by-pass mode. A 6 inch diameter, 12 mm high single pancake 2 G wire coil operating at 77 K was used as the magnetic storage. The measured coil inductance was 3.0 mH at 70 A, 77 K. In the superconducting by-pass mode the current passed through a MOSFET mounted directly on the coil terminations. The L/R (inductance divided by resistance) time constant was 11 seconds, which is consistent with the average MOSFET channel resistance 270μΩ at 77 K, (see FIG. 8A). In the superconducting by-pass mode the equivalent resistance was that of superconducting joints. Since the joint resistance is on the order of 10⁻⁸Ω, a much greater time constant as high as 10⁵ s, or over 10 hr can be achieved.

### Example 3

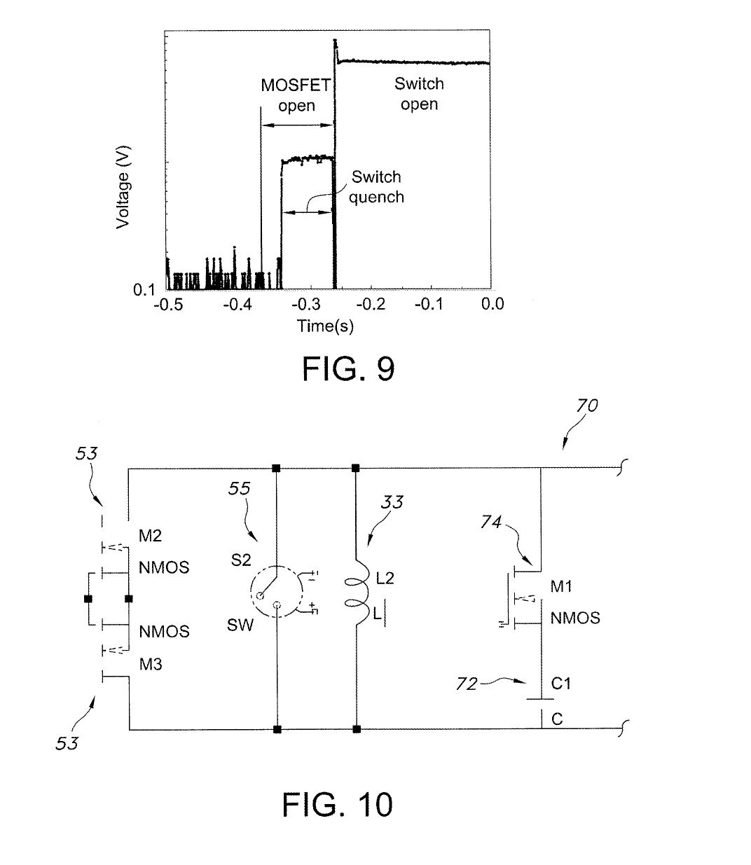

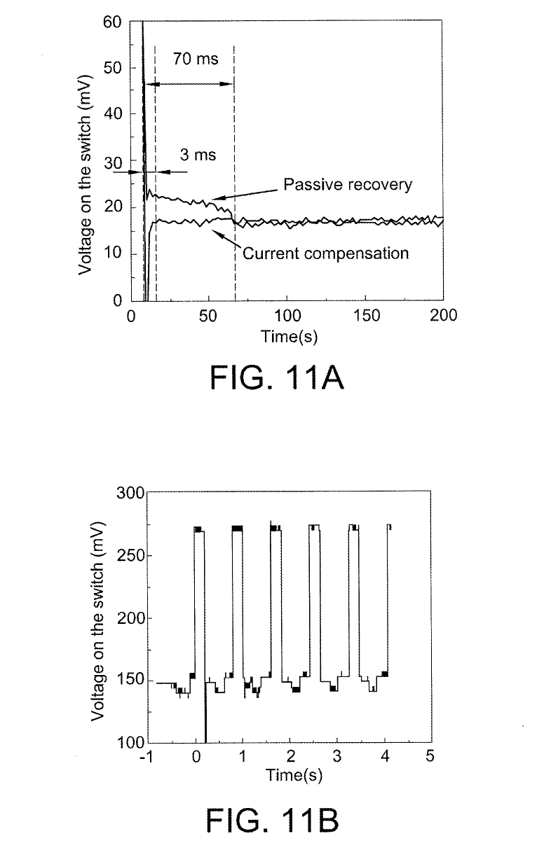

The two phases of the switch operation at 77 K, 30 A, are shown in FIG. 9. The switch quench occurs within 50 ms. The MOSFET prevent the voltage from rising over the damaging level, typically several millivolts. Once the YBCO switch wire is in the normal state, the MOSFET can be opened and the voltage can rise to the operating level, corresponding to the “off” state. The closing, or recovery, phase of the switch operation is recognized as the most critical step (see FIG. 11A). In the recovery phase the switch transitions from normal “off” state to superconducting “on” state. The simplest closing procedure is to turn on the parallel MOSFET and allow the superconducting layer to cool down. The FEM model based on uniform heat transfer predicted that the switch closing time would recover and close within 10 ms. However, experimental recovery time can exceed several seconds, especially for large current. Much faster closing can be achieved by actively redirecting the current from the switch by opening the recovery MOSFET.

To speed up the recovery process, a circuit was implemented which delivers an opposite current through the switch during re-closure phase (see FIGS. 10 and 11A). This measure allows for a fast, less than 3 ms switch closure. FIG. 11B demonstrates a continuous operation of the superconducting switch with frequency 1 Hz.

### Example 4

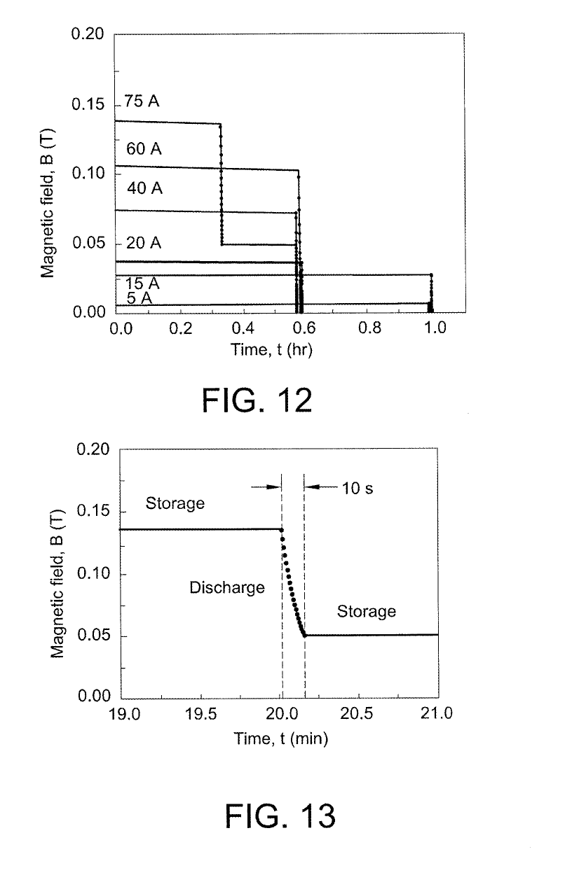

FIG. 12 shows the time dependencies of the axial component of the magnetic field in the storage mode (the persistent switch is “on”) at coil current ranging from 5 to 75 A. Time profiles of the axial field component of the 6″ coil in the storage mode. FIG. 13 is a detailed profile of the partial discharge of the coil from 75 A to 20 A. The profile demonstrates transition from discharge to the storage mode with 10 sec in a storage application. The 10 s time includes transition of the switch from the superconducting to normal state, discharging of the coil for 4 seconds and transition of the switch to the superconducting state (storage mode).

### Example 5

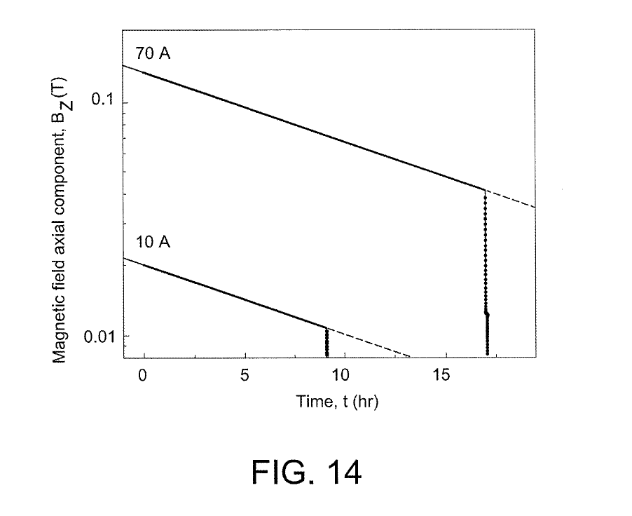

FIG. 14 presents long-term field time profiles at 10 and 70 A coil current. The solid line are exponential decay approximation B(t)=B(0)e^{-t/τ}, where τ=14.3 hr. The time constant value indicates that the primary source of the loss is dissipation in the joints. Taking L=3.0 mH the equivalent circuit resistivity R=64 nΩ was calculated. The measured resistivity of the 1.5 cm long lap joints used in this experiment is on average 40 nΩ, hence the equivalent resistivity is well accounted for by the series connection of two joints.

All publications and patents mentioned in the above specification are incorporated by reference in their entireties in this disclosure. Various modifications and variations of the described materials and methods will be apparent to those skilled in the art without departing from the scope and spirit of the invention. Although the disclosure has been described in connection with specific preferred embodiments, it should be understood that the invention as claimed should not be unduly limited to such specific embodiments. Indeed, those skilled in the art will recognize, or be able to ascertain using the teaching of this disclosure and no more than routine experimentation, many equivalents to the specific embodiments of the disclosed invention described. Such equivalents are intended to be encompassed by the following claims.

1. An energy storage system, comprising:
a cryostat;
a superconducting electromagnet disposed within the cryostat, and having first and second leads; and
a persistent switch coupled to the first and second leads of the superconducting electromagnet and disposed within the cryostat,
wherein the persistent switch comprises:
a heating element; and
a length of wire having at least one strand of superconducting material in thermal contact with the heating element, the wire having first and second ends connected to the first and second leads, wherein the wire becomes resistive above a superconducting critical temperature.

2. The energy storage system of claim 1, further comprising a high frequency alternating current (AC) power source electrically connected to the heating element for applying a current through the heating element, thereby directly heating the heating element for raising the temperature of the wire to its superconducting critical temperature.

3. The energy storage system of claim 1, further comprising a high frequency alternating current (AC) power source and an inductive heater electrically connected to the power source, the inductive heater being disposed in close proximity to the heating element for indirectly heating the heating element for raising the temperature of the wire to its superconducting critical temperature.

4. The energy storage system of claim 1, wherein the heating element is selected from nickel, nickel-tungsten alloy, stainless steel, or superalloy.

5. The energy storage system of claim 1, wherein the heating element is between 20 and 100 μM thick.

6. The energy storage system of claim 5, wherein the heating element is about 50 μm thick.

7. The energy storage system of claim 1, wherein the superconducting material is selected from yttrium barium copper oxide (YBCO) or bismuth strontium calcium copper oxide (BiSCCO).

8. The energy storage system of claim 1, wherein the strand of superconducting material is between 0.5 and 10 μm thick.

9. The energy storage system of claim 8, wherein the strand of superconducting material is about 1 μm.

10. The energy storage system of claim 1, wherein the number of strands is 6 having the dimensions of 10 mm by 20 cm.

11. The energy storage system of claim 1, wherein the persistent switch further comprises a by-pass module connected in parallel with the length of wire between the first and second leads for allowing current by-pass during a transition from superconducting to resistive mode of the wire.

12. The energy storage system of claim 11, wherein the by-pass module comprises one or more low-resistance metal oxide semiconductor field-effect transistors (MOSFETs).

13. The energy storage system of claim 12, wherein the metal oxide semiconductor field-effect transistor reaches a minimum at about 77 K.

14. The energy storage system of claim 1, further comprising a bus bar connecting first, second or both leads of the superconducting electromagnet to a power conditioning system.

15. The energy storage system of claim 14, wherein the bus bar is made from copper or aluminum.

16. The energy storage system of claim 1, further comprising at least two metal plates, wherein the wire is sandwiched therebetween.

17. The energy storage system of claim 1, the superconducting material has a critical temperature between 60 K and 120 K.

19. A superconducting persistent switch, comprising:
a first lead that comprises a superconducting material;
a second lead that comprises a superconducting material;
a heating element; and
a length of wire having at least one strand of superconducting material in thermal contact with the heating element, the wire having first and second ends connected to the first and second leads, wherein the wire becomes resistive above a superconducting critical temperature.

20. The switch of claim 19, further comprising a by-pass module connected in parallel with the length of wire between the first and second leads for allowing current by-pass during a transition from superconducting to resistive mode of the wire.

21. The switch of claim 20, wherein the by-pass module comprises one or more low-resistance metal oxide semiconductor field-effect transistors (MOSFETs).

22. The switch of claim 20, wherein the by-pass module has a channel resistance minimum at about 77 K.

23. The switch of claim 19, further comprising a copper or an aluminum bus bar attached to the first and the second leads.

24. The switch of claim 19, further comprising at least two metal plates wherein the wire is sandwiched between the two metal plates.

25. The switch of claim 19, wherein the superconducting material is yttrium barium copper oxide (YBCO).

26. The switch of claim 19, wherein the superconducting material is bismuth strontium calcium copper oxide (BiSCCO).

27. The switch of claim 19, wherein the heating element is made from a metal substrate selected from nickel, nickel-tungsten alloy, stainless steel, or superalloy.

28. The switch of claim 27, wherein the superalloy is selected from inconel, hastelloy, or nichrome.

29. The switch of claim 19, wherein the wire is in a shape of a loop having a substantially edge free cross-section.

30. The switch of claim 29, wherein the wire is in the shape of a flattened cylinder.

31. A method of operating a superconducting energy storage system comprising:
conducting current through a superconducting electromagnet circuit having a superconducting magnet with first and second superconducting leads coupled to a power conditioning system and a superconducting persistent switch, the persistent switch including a heating element and a length of wire having at least one strand of superconducting material in thermal contact with the heating element, the wire having first and second ends connected to the first and second leads; and
generating a high frequency alternating current to heat the heating element of the persistent switch to heat the superconducting material of the wire in the persistent switch from a superconducting state to a resistive state.

32. A method of claim 31, wherein the high frequency alternating current is passed through the heating element, thereby directly heating the heating element.

33. The method of claim 31, wherein the high frequency alternating current is applied to an inductive heater disposed in close proximity to the heating element for indirectly heating the heating element.

34. The method of claim 31, wherein the persistent switch further includes a by-pass module coupled to the first and second leads, and the method further comprises opening the by-pass module to allow the voltage to rise to an operating level.

35. The method of claim 31, wherein the persistent switch comprises a length of wire having a plurality of strands of superconducting material.

36. The method of claim 31, further comprising cooling a cryostat, within which the superconducting electromagnet and the persistent switch are contained, to a sufficiently low temperature so that the electromagnet and persistent switch are placed in a superconducting state.

37. The method of claim 31, wherein the superconducting electromagnet and the persistent switch are connected in parallel with one another.
